(19) United States
(12) Patent Application Publication
(10) Pub. No.: US 2002/0164544 A1
(43) Pub. Date: Nov. 7, 2002

(54) Dual damascene using removable via studs

(75) Inventors: Todd P. Luckanc, San Jose, CA (US); Scott A. Bell, San Jose, CA (US); Christopher F. Lyons, Fremont, CA (US); Marina V. Plat, San Jose, CA (US); Ramkumar Subramanian, Sunnyvale, CA (US)

Correspondence Address: David A. Blumenthal, FOLEY & LARDNER, Washington Harbour, 3000 K Street, N.W., Suite 500, Washington, DC, 20007-5109, US

(73) Assignee: ADVANCED MICRO DEVICES, INC.

(21) Appl. No.: 09/846,369

(22) Filed: May 2, 2001

(51) Int. Cl. G03F 7/00

(52) U.S. Cl. 430/314; 430/311; 430/313; 430/316; 430/317

(57) ABSTRACT

A dual damascene process is described. A sacrificial post is formed using a photolithographic process which may include exposing photoresist through a bright field photomask. An interlevel dielectric, such as a low-k dielectric, is formed on the post, and a trench etched exposing the post. The post is then removed, thereby forming a hole. A conducting layer is then formed in the hole and the trench.

### FIELD OF THE INVENTION

This invention relates generally to dual damascene processes in semiconductor device fabrication. In particular, this invention relates to a dual damascene process using removable via studs (posts) in semiconductor device fabrication.

### DESCRIPTION OF THE RELATED ART

A continuing trend in semiconductor devices is the reduction of feature size to decrease the distance between components on devices and thus increase device speed and computational power of devices. Photolithographic processes used for forming features have addressed the reduction in size and lowered the critical dimension (CD) attainable in a device, at least in part, through the use of ever decreasing wavelengths of electromagnetic radiation, i.e., light, to expose feature patterns on photoresist.

One important feature in a semiconductor device is the via hole, for connecting different layers of wiring in the device. In a typical dual damascene process, via holes and trenches connecting the via holes are formed in an inter-level dielectric (ILD), and the trench and vias are then filled with a conductive material that connects to underlying conducting material on the device through the via holes. Conventionally, separate resist masks and separate etches are used for patterning the via holes, and the trench.

In forming the via hole, dark field photomasks are typically used for patterning the masking photoresist. Dark field photomasks are masks where most of the mask is opaque with only a fraction of the mask transparent. For bright field photomasks, the reverse is true, i.e., most of the mask is transpatent with only a fraction of the mask opaque. In the process of forming via holes using a dark field mask, photoresist is exposed through the dark field mask, and the exposed regions of the photoresist are then removed to form a photoresist etch mask for the via holes. The via holes are then etched through the photoresist etch mask.

### SUMMARY OF THE INVENTION

According to an embodiment of the present invention to provide a method for reliably forming a via hole in a trench in a dual damascene process. The method includes a step of providing a first conducting layer over a substrate. A post is formed over the first conducting layer. An ILD is formed over the post and the first conducting layer. A trench is then formed in the ILD exposing the post. The post is removed thereby forming a hole to the first conducting layer. A second conducting layer is then formed in the trench and the hole to electrically connect to the first conducting layer. The ILD is preferably a low-k dielectric.

The post is preferably formed using a photolithographic process including exposing photoresist through a bright field mask. In this regard, a post material is formed over the first conducting layer. Photoresist is formed over the post material. Electromagnetic radiation is directed through a photomask using a bright field photomask with a post pattern to the photoresist. The photoresist is developed to form a photoresist mask over the post material. The post material is then etched using the photoresist mask as an etch mask to form a post over the first conducting layer.

### BRIEF DESCRIPTION OF THE DRAWINGS

These and other objects and advantages of the present invention will become more fully apparent from the following detailed description when read in conjunction with the accompanying drawings with like reference numerals indicating corresponding parts throughout, wherein:

FIGS. 1A-1G illustrate cross-sectional views of the dual damascene process in accordance with an embodiment of the present invention.

FIG. 2 illustrates a cross-sectional view of the dual damascene process in accordance with an embodiment of the present invention where the post material is not removed.

### DETAILED DESCRIPTION OF THE PREFERRED EMBODIMENT

Because bright field masking is easier to control then dark field masking, it is easier to control the dimensions of a post using a bright field mask, than to control the dimensions of a similar sized via hole formed using a dark field mask. This control is especially important for patterns with critical dimensions less than 100 nanometers.

Thus, a via hole is formed in a dual damscene process using a sacrificial post. An ILD if formed around the sacrificial post. The sacrificial post is removed to form a via hole.

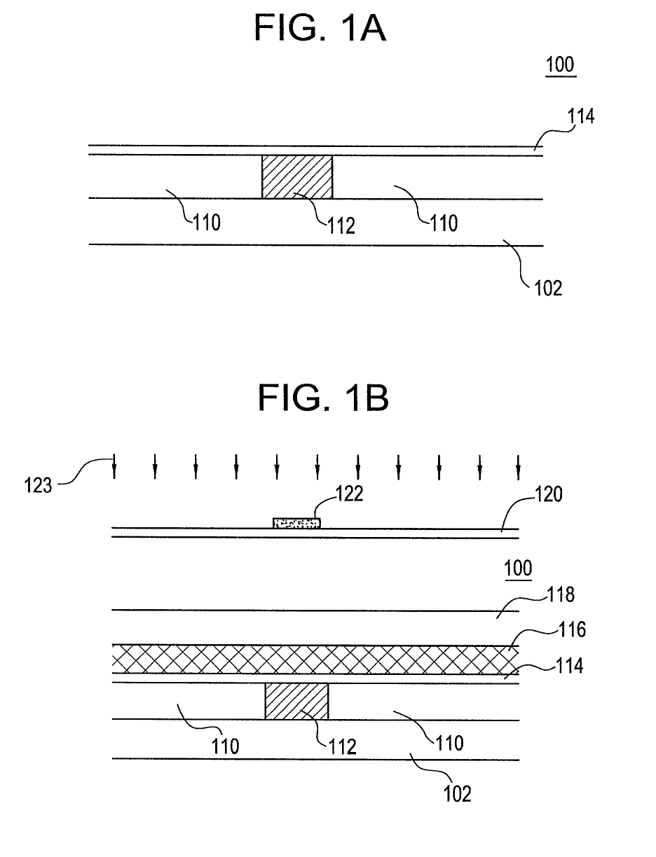

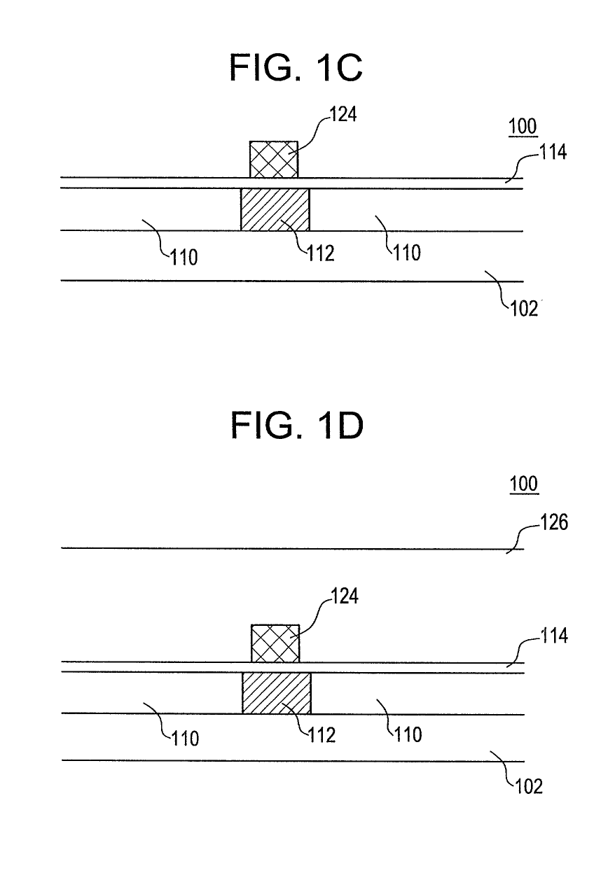

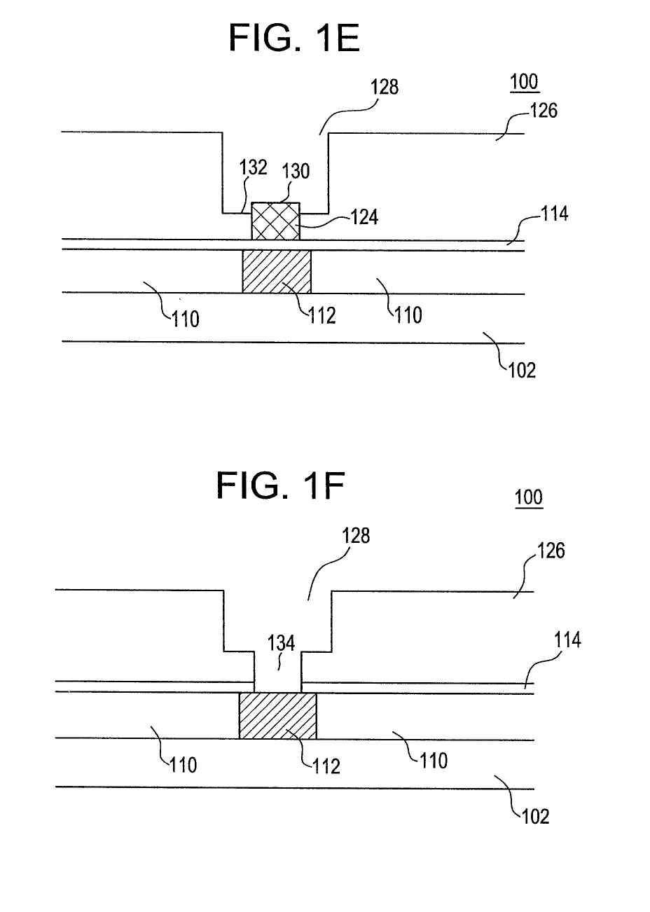

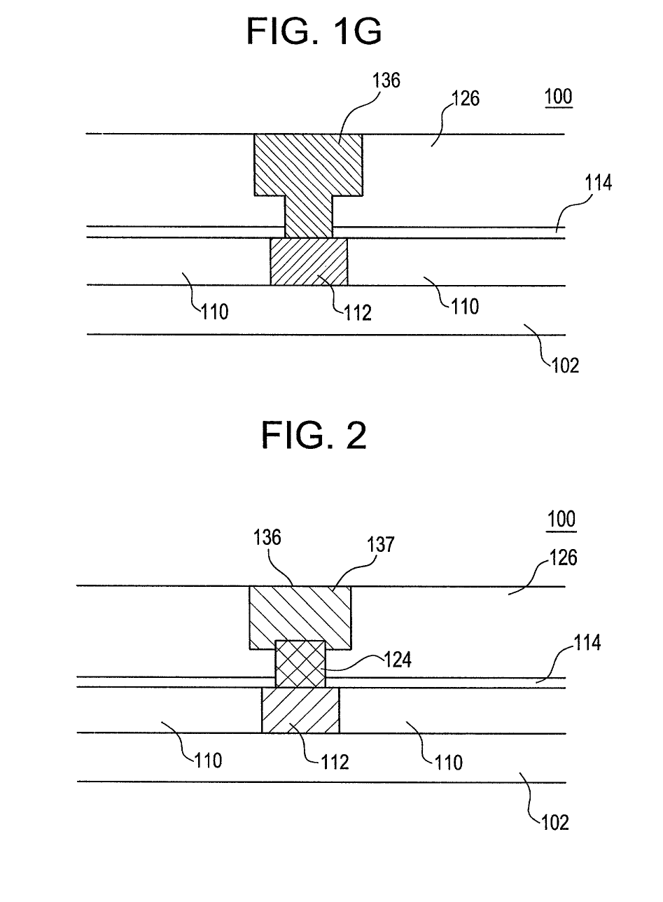

The embodiments of the present invention will now be explained with respect to FIGS. 1A-1G. FIG. 1A shows a portion of a semiconductor device 100 including a semiconductor substrate 102. A first conducting layer 112 is formed over the semiconductor substrate 102. The first conducting layer 112 in FIG. 1A is an interconnect connecting to different regions of the semiconductor substrate 102. The first conducting layer 112 is formed in a first ILD 110.

The first ILD 110 may be, for example, a low-k dielectric to reduce capacitance between conducting regions of the semiconductor device 100. By reducing the capacitance between conducting regions, the low-k dielectric reduces the interline capacitance, thereby reducing the RC delay, cross-talk noise and power dissipation in the interconnects. In this application low-k dielectric means a dielectric with a dielectric constant of less than about 4. Suitable low-k dielectrics are, for example, benzocyclobutene (BCB), hydrogen silsequioxane (HSQ), FLARE, which is a commercially known material manufactured by Allied Signal, and SILK.

The first conducting layer 112 in FIG. 1A comprises, for example, copper or a copper alloy. The first conducting layer 112 may alternatively comprise, for example, aluminum, an aluminum alloy, tungsten, or a tungsten alloy. Preferably, if the first conducting layer is copper or a copper alloy, the first conducting layer is lined with a lining material (not shown) between the ILD 110 and the first conducting layer 112.

The lining material may act as a barrier layer to prevent diffusion of material between the first conducting layer 112 and the ILD 110. The lining material may also function as an adhesion promoter. Suitable examples of lining material include TiN, TiSiN, Ta, TaN, TaSiN, WN, WSiN, SiO₂, SiN, Al₂O₃, SiC and SiON. If the first conducting layer 112 is copper a lining material such as TiN or TaN may be preferred.

The first conducting layer 112 may be formed by any suitable process, such as chemical vapor deposition (CVD), plasma enhanced chemical vapor deposition (PECVD), plating, or sputtering.

The first conducting layer 112 may be formed, for example, by blanket deposition of conducting material followed by either etch-back or polishing to remove undesired conducting material. Alternatively, the first conducting layer 112 may be formed by selective deposition of conducting material. If the first conducting layer 112 is formed by selective deposition, the lining material may act as an adhesion promoter or nucleation material.

Although the first conducting layer 112 is shown in FIG. 1A to be an interconnect, the first conducting layer 112 may alternatively be a region of the semiconductor substrate 102, such as a doped region of the substrate 102. The first conducting layer 112 may be, for example, a p-type or n-type region of the semiconductor substrate 112.

After the first conducting layer 112 is formed, a cap layer 114 may optionally be formed to protect the first conducting layer 112 by acting as a barrier layer. The cap layer 114 may also be chosen to act as an adhesion promoter for subsequent layers to be formed on the cap layer 114. The cap layer 114 may be, for example, silicon nitride (SiN) when the first conducting layer is copper. The silicon nitride may be deposited, for example, by chemical vapor deposition (CVD). If the first conducting layer is aluminum, the cap layer may be SiN or SiO₂.

FIG. 1B illustrates a photomask 120 positioned over a photoresist layer 118 and a post material layer 116. The post material layer 116 may be formed by blanket depositing post material over the first conducting layer 112 and the ILD 110. The term “over” includes the possibility that there may be intervening layers, such as cap layer 114, between post material layer 116 and the underlying first conducting layer 112 and ILD 110. After the post material 116 is deposited over the first conducting layer 112, the photoresist layer 118 is formed over the post material layer 116. The post material layer 116 may include aluminum, aluminum alloys, polycrystalline silicon (polysilicon), and amorphous silicon. The post material may also be an insulating material such as SiO₂ or SiN₂. In any case it is preferred that the post be of a material that can be preferentially etched relative to a subsequently deposited second ILD layer, described below. The photoresist layer 118 may be formed, for example, by spinning on the photoresist, as is known in the art.

The photomask 120 shown in this embodiment is a bright field mask, i.e., most of the mask comprises regions transparent to exposing electromagnetic radiation 123. The photomask 120 also includes opaque regions 122 in the pattern of the post to be formed. The opaque regions 122 may be, for example, chrome or some other material opaque to the exposing electromagnetic radiation, as is known in the art. The exposing electromagnetic radiation 123 may be, for example, ultraviolet (UV) radiation or deep-UV radiation.

The underlying photoresist layer 118 is exposed to the exposing electromagnetic radiation 123 through the photomask 120. The photoresist layer 118 is then developed to remove the regions of the photoresist which have not been exposed. In this regard, when a bright field mask is used, the photoresist should be chosen such that when it is developed, exposed regions of the photoresist are removed. Thus, the photoresist is a positive photoresist. In a less preferred embodiment, a dark field mask can be used in combination with a negative resist, where unexposed regions of the resist are removed upon developing.

After the photoresist layer 118 has been patterned, the post material layer 116 is patterned using the patterned photoresist as an etch mask. The particular etch used will depend upon the post material chosen, and is preferably a directional etch such as reactive ion etching (RIE).

FIG. 1C shows the post 124 formed over the first conducting layer 112 after the post material 116 has been patterned.

FIG. 1D shows a second ILD 126 formed over the post 124. The second ILD 126, like the first ILD 110, may be, for example, a low-k dielectric to reduce capacitance between conducting regions of the semiconductor device 100. Suitable low-k dielectrics are, for example, benzocyclobutene (BCB), hydrogen silsequioxane (HSQ), FLARE, which is a commercially known material manufactured by Allied Signal, and SILK.

After the second ILD 126 is formed, a hole or trench 128 is formed in the second ILD 126 to expose the post 124 as shown in FIG. 1E. The trench 128 may be formed, for example, by etching the second ILD layer 126 through a suitable etch mask. The trench 128 is etched to expose the post 124. In this regard, the trench bottom surface 132 may be etched below the post top surface 130. Alternatively, the trench bottom surface 132 and the post top surface 130 may be at the same height.

The trench etch to expose the post 124 may be a timed etch. Alternatively, the trench etch to expose the post 124 may be an endpoint detection etch. For example, if the post 124 is formed of aluminum, the endpoint of the etch, i.e., when the aluminum is exposed, may be detected as is known in the art, and the etch stopped at that point in time.

The view shown in FIG. 1E shows only a single post 124 formed. In practice of certain embodiments of the invention, many posts will be formed, one post for each via to be formed by removing the respective post, as explained below. For example, it would be expected that forming a trench may expose two or more posts, and that there would be many trenches. Subsequent filling of the trench with conducting material after removal of the post material will electrically connect portions of the first conducting layer 112 directly under the respective vias in a particular trench.

After the post 124 is exposed in the trench etch, the post is then removed to leave a via 134 as shown in FIG. 1F. The post is removed, preferably, by etching away the post 124 with an etchant that is selective to the post 124 over the second ILD 126. In this regard, an embodiment of the present invention provides the advantage that the post material may be chosen specifically so that in the removal of the post 124 through etching, the etch is highly selective to the post. Because the post 124 is simply a sacrificial material, the post may be chosen only for its selective etch properties. Moreover, there is no need for a directional etch, and a isotropic wet etch may be readily used to remove the post 124. Examples of the post material include aluminum, aluminum alloys, polycrystalline silicon (polysilicon), and amorphous silicon. The post material may also be an insulating material such as SiO₂ or SiNₓ.

If a cap layer 114 is formed, and the cap layer 114 has not been etched to expose the first conducting layer 112 prior to forming the post 124, the cap layer 114 should be etched to expose the first conducting layer 112 after removing the post 124. The etching of the cap layer 114 to expose the first conducting layer 112 may be performed as part of the same etching step as that of the post 124, and may include the same etchants as in the etching step of removing the post. Alternatively, etching the cap layer to expose the first conducting layer may be performed in a different etching step using different etchants. For example, the cap layer 114 may be removed as an initial step prior to forming a second conducting layer as described below with respect to FIG. 1G.

FIG. 1G shows the semiconductor device 100 with the trench 128 and via 134 filled with a second conducting layer 136. The second conducting layer 136 may be formed, for example, by blanket depositing a second conducting material over the substrate 102 and in the trench 128 and via 134, followed by removing a top portion of the second conducting layer until a top surface 138 of the second conducting layer 136 is substantially at a same height as a top surface 140 of the second ILD 126. The top portion of the second conducting layer 136 may be removed, for example, by etching back or polishing the second conducting layer. The polishing of the second conducting layer 136 may be a chemical mechanical polishing, for example.

The second conducting layer 136 in FIG. 1G comprises, for example, copper or a copper alloy. The second conducting layer 136 may alternatively comprise, for example, aluminum, an aluminum alloy, tungsten, or a tungsten alloy. Preferably, if the second conducting layer is copper or a copper alloy, the second conducting layer is lined with a lining material (not shown) between the second ILD 126 and the second conducting layer 136.

The lining material may act as a barrier layer to prevent diffusion between the second conducting layer 136 and the second ILD 126. Suitable examples of lining material include TiN, TiSiN, Ta, TaN, TaSiN, WN, WSIN, SiO₂, SiN, Al₂O₃, SiC and SION. If the second conducting layer is copper a lining material such as TiN or TaN may be preferred.

The second conducting layer 136 may be formed by any suitable process, such as chemical vapor deposition (CVD), plasma enhanced chemical vapor deposition (PECVD), plating or sputtering.

Alternatively, the second conducting layer 136 may be formed by selective deposition of conducting material. If the second conducting layer 136 is formed by selective deposition, the lining material may be chosen to act as an adhesion promoter or nucleation material.

FIG. 1F shows the post material being removed as a sacrificial material. As an alternative, as illustrated in FIG. 2, the post material is a conducting material, and is left in place instead of removing it. In this case, the post material will act as a conducting via fill. Also in this case if a cap layer 114 is formed, the cap layer 114 should be etched prior to forming the post 124, so that the post 124 will electrically contact the first conducting layer 112 as illustrated in FIG. 2. Also, as shown in FIG. 2, the second conducting layer 136 comprises both a second conducting layer top portion 137 and the post 124.

In some of the above embodiments, photolithography was used in patterning the post. Alternatively, e-beam lithography may be used to pattern the post.

While there has been illustrated and described what is at present considered to be preferred embodiments of the present invention, it will be understood by those skilled in the art that various changes and modifications may be made, and equivalents may be substituted for elements thereof without departing from the true scope of the invention. In addition, many modifications may be made to adapt a particular situation or material to the teachings of the invention without departing from the central scope thereof. Therefore, it is intended that this invention not be limited to the particular embodiment disclosed as the best mode contemplated for carrying out the invention, but that the invention will include all embodiments falling within the scope of the appended claims.

What is claimed is:

1. A method of forming a semiconductor device comprising:
providing a first conducting layer over a substrate;
forming a post over the first conducting layer;
forming an inter-level dielectric (ILD) over the first conducting layer and the post;
forming a trench in the ILD thereby exposing the post;
removing the post thereby forming a hole over the first conducting layer; and
forming a second conducting layer in the trench and the hole to electrically connect to the first conducting layer.

2. The method of forming a semiconductor device according to claim 1, where the forming a post step comprises:
forming a post material over the first conducting layer; and
etching the post material to form the post.

3. The method of forming a semiconductor device according to claim 2, where the etching the post material comprises a timed etch.

4. The method of forming a semiconductor device according to claim 2, where the etching the post material comprises an endpoint detected etch.

5. The method of forming a semiconductor device according to claim 2, wherein the step of forming a post further comprises:
forming a photoresist layer over the post material;
directing electromagnetic radiation through a bright field photomask with a post pattern to the photoresist layer; and
developing the photoresist layer to form a photoresist mask over the post material, and
wherein the etching the post material is performed using the photoresist mask as an etch mask.

6. The method of forming a semiconductor device according to claim 1, wherein the removing step comprises etching the post.

7. The method of forming a semiconductor device according to claim 6, wherein the removing step comprises wet etching the post.

8. The method of forming a semiconductor device according to claim 7, wherein the wet etch is selective to the post over the ILD.

9. The method of forming a semiconductor device according to claim 1, wherein the post comprises a metal.

10. The method of forming a semiconductor device according to claim 9, wherein the post comprises one of aluminum, an aluminum alloy, polycrystalline silicon, amorphous silicon, SiO₂ and SiNₓ.

11. The method of forming a semiconductor device according to claim 1, wherein the first conducting layer comprises one of an aluminum layer, an aluminum alloy layer, a tungsten layer, a tungsten alloy layer, a copper layer, and a copper alloy layer.

12. The method of forming a semiconductor device according to claim 11, further comprising:
forming a cap layer on the first conducting layer prior to forming the ILD; and
the step of removing the post includes etching a portion of the cap layer between the post and the first conducting layer.

13. The method of forming a semiconductor device according to claim 12, wherein the cap layer is one of SiO₂ and SiN.

14. The method of forming a semiconductor device according to claim 1, wherein the ILD comprises a low-k dielectric layer.

15. The method of forming a semiconductor device according to claim 14, wherein the low-k dielectric layer is one of benzocyclobutene (BCB), hydrogen silsequioxane (HSQ), FLARE, and SILK.

16. The method of forming a semiconductor device according to claim 14, wherein the removing the post step comprises wet etching the post, and the wet etch is selective to the post over the ILD.

17. The method of forming a semiconductor device according to claim 1, wherein the post has a top surface and the trench has a bottom surface, and wherein in the step of forming a trench in the ILD, the trench bottom surface is formed below the post top surface.

18. The method of forming a semiconductor device according to claim 1, wherein the second conducting layer comprises one of an aluminum layer, an aluminum alloy layer, a tungsten layer, a tungsten alloy layer, a copper layer, and a copper alloy layer.

19. The method of forming a semiconductor device according to claim 18, wherein the second conducting layer comprises one of a copper layer, and a copper alloy layer.

20. The method of forming a semiconductor device according to claim 19, further comprising:
forming a liner layer prior to forming the second conducting layer.

21. The method of forming a semiconductor device according to claim 20 wherein the liner layer comprises one of TiN, TiSiN, Ta, TaN, TaSiN, WN, WSiN, SiO₂, SiN, Al₂O₃, SiC and SiON.

22. The method of forming a semiconductor device according to claim 1, wherein the ILD has a top surface, the method further comprising:
removing a top portion of the second conducting layer so that a top surface of the second conducting layer is at substantially a same height as a top surface of the ILD.

23. The method of forming a semiconductor device according to claim 22, wherein the removing a top portion step comprises one of polishing and etching back the top portion.

24. A method of forming a semiconductor device comprising:
providing a first conducting layer over a substrate;
forming a post over the first conducting layer;
forming a low-k inter-level dielectric (ILD) layer over the first conducting layer and the post;
forming a trench in the low-k ILD thereby exposing the post;
etching and thereby removing the post to form a hole over the first conducting layer, where the etching is selective to the post over the low-k ILD; and
forming a second conducting layer in the trench and the hole to electrically connect to the first conducting layer.

25. The method of forming a semiconductor device according to claim 24, wherein the low-k ILD is one of benzocyclobutene (BCB), hydrogen silsequioxane (HSQ), FLARE, and SILK.

26. The method of forming a semiconductor device according to claim 24, where the forming a post step comprises:
forming a post material over the first conducting layer; and
etching the post material to form the post.

27. The method of forming a semiconductor device according to claim 26, wherein the forming a post step further comprises:
forming a photoresist layer over the post material;
directing electromagnetic radiation through a bright field photomask with a post pattern to the photoresist layer; and
developing the photoresist layer to form a photoresist mask over the post material, and wherein the etching the post material is performed using the photoresist mask as an etch mask.

28. The method of forming a semiconductor device according to claim 24, wherein the etching step comprises wet etching the post.

29. The method of forming a semiconductor device according to claim 24, wherein the post comprises a metal.

30. The method of forming a semiconductor device according to claim 29, wherein the post comprises one of aluminum, an aluminum alloy, polycrystalline silicon, amorphous silicon, SiO₂ and SiNₓ.

31. The method of forming a semiconductor device according to claim 24, wherein the first conducting layer comprises one of an aluminum layer, an aluminum alloy layer, a tungsten layer, a tungsten alloy layer, a copper layer, and a copper alloy layer.

32. The method of forming a semiconductor device according to claim 31, further comprising:
forming a cap layer on the first conducting layer prior to forming the low-k ILD; and
the step of removing the post includes etching a portion of the cap layer between the post and the first conducting layer.

33. The method of forming a semiconductor device according to claim 24, wherein the post has a top surface and the trench has a bottom surface, and wherein in the step of forming a trench in the low-k ILD, the trench bottom surface is formed below the post top surface.

34. The method of forming a semiconductor device according to claim 24, wherein the second conducting layer comprises one of an aluminum layer, an aluminum alloy layer, a tungsten layer, a tungsten alloy layer, a copper layer, and a copper alloy layer.

35. The method of forming a semiconductor device according to claim 34, wherein the second conducting layer comprises one of a copper layer, and a copper alloy layer.

36. The method of forming a semiconductor device according to claim 34, further comprising:
forming a liner layer prior to forming the second conducting layer.

37. The method of forming a semiconductor device according to claim 24, wherein the low-k ILD has a top surface, the method further comprising:
removing a top portion of the second conducting layer so that a top surface of the second conducting layer is at substantially the same height as the top surface of the ILD.

38. The method of forming a semiconductor device according to claim 37, wherein the removing a top portion step comprises one of polishing and etching back the top portion.

39. A method of forming a semiconductor device comprising:
providing a first conducting layer over a substrate;
forming a post material over the first conducting layer;
forming a photoresist layer over the post material;
directing electromagnetic radiation through a photomask with a post pattern to the photoresist layer;
developing the photoresist to form a photoresist mask over the post material;
etching the post material using the photoresist mask as an etch mask to form a post over the first conducting layer;
forming an inter-level dielectric (ILD) over the first conducting layer and the post;
forming a trench in the ILD thereby exposing the post;
removing the post thereby forming a hole over the first conducting layer; and
forming a second conducting layer in the trench and the hole to electrically connect to the first conducting layer.

40. The method of forming a semiconductor device according to claim 39, wherein the photomask is a bright field mask.

41. The method of forming a semiconductor device according to claim 39, wherein the photomask is a dark field mask.

42. A method of forming a semiconductor device comprising:
providing a first conducting layer over a substrate;
forming a post over the first conducting layer;
forming an inter-level dielectric (ILD) over the first conducting layer and the post;
forming a first hole in the ILD thereby exposing the post;
removing the post thereby forming a second hole in the first hole and over the first conducting layer; and
forming a second conducting layer in the first hole and the second hole to electrically connect to the first conducting layer.
